(19) United States
(12) Patent Application Publication
(10) Pub. No.: US 2011/0051206 A1
(43) Pub. Date: Mar. 3, 2011

(54) CORRECTING COLOR BASED ON AUTOMATICALLY DETERMINED MEDIA

(76) Inventors: Steven C. Sitter, Fairport, NY (US); Katherine Miller-Mullins, Canandaigua, NY (US)

(21) Appl. No.: 12/549,837

(22) Filed: Aug. 28, 2009

(51) Int. Cl. G03F 3/08

(52) U.S. Cl. 358/518

(57) ABSTRACT

A method for automatically applying color transforms to scanned input images from a digital color image scanner, wherein the input images may be on a variety of different imaging media is disclosed and comprised of: scanning a front side of an input image forming an image scan, scanning a back side of the input image forming a back scan, analyzing the image scan or the back scan to determine the imaging medium for the scanned input image, selecting a color transform associated with the determined imaging medium and applying the color transform to the image scan to produce a corrected image scan.

### CROSS REFERENCE TO RELATED APPLICATIONS

Reference is made to commonly assigned, co-pending U.S. patent application Ser. No. 12/491,268 filed Jun. 25, 2009, entitled: “Dating Images from Scanned Watermarks”, by A. Scalise, et al. (Docket 95650), which is incorporated herein by reference.

### FIELD OF THE INVENTION

The present invention relates to the color correction of digitally scanned images, and more particularly, to a method for automatically determining the imaging media and selecting a corresponding color correction transform.

### BACKGROUND OF THE INVENTION

Human eyes contain cones having three different spectral sensitivities, which is the basis of human color vision. Typical human cone spectral sensitivities are shown in FIG. 1, and are labeled ρ, γ and β. It can be seen that the peak sensitivities for each of the different cone types occurs at different wavelengths of light. The β cones are most sensitive to “blue” light of about 450 nm, whereas the γ and ρ cones have peak sensitivities at about 550 nm and 580 nm, respectively, covering the “green” and “red” portions of the spectrum. Objects of different colors arc distinguished by having different spectral reflectances, and therefore will stimulate different relative responses in each of the different cone types. A key principal for understanding color vision is that any two objects that produce the same cone responses will be seen to have the same color. Color is typically measured by calculating the well-known CIE XYZ tristimulus values:

$$X = {\int }_{400}^{700} I ( λ ) R ( λ ) \overline{x} ( λ ) d λ \\ Y = {\int }_{400}^{700} I ( λ ) R ( λ ) \overline{y} ( λ ) d λ \\ Z = {\int }_{400}^{700} I ( λ ) R ( λ ) \overline{z} ( λ ) d λ \qquad ( 1 )$$

where λ is the wavelength, I(λ) is the spectral power of the light source, R(λ) is the spectral reflectance of the object, and x̅(λ), y̅(λ) and z̅(λ) are the color matching functions, which are convenient linear combinations of the cone spectral sensitivity functions. Any two objects having the same XYZ values will appear to have the same color to a human observer.

Often it is desirable to be able to scan a color image to form a digital image that can be viewed, manipulated and/or stored in a digital computer Because of the tri-chromatic nature of human color vision, a digital color image scanner must fundamentally have three different types of color sensors in order to be able to infer the color of the original image. The three different types of color sensors are generally chosen to be sensitive to the red, green and blue regions of the visible spectrum.

A set of typical spectral sensitivities for a digital color image scanner are shown in FIG. 2. It can be seen that these spectral sensitivities differ substantially from those of the human vision system shown in FIG. 1. This fact gives rise to a phenomenon known as scanner metamerism errors. This occurs when two objects match when viewed by a human observer, but which do not match when then are scanned with the scanner. Consider the case when two images formed on different imaging media are scanned on a digital color image scanner. If both images contain an image region of neutral gray, which appear to be identical to the human eye, it would be desirable that the scanner would produce identical scanner code values for these image regions. However, it is commonly found that the two image regions may produce substantially different scanner code values. This occurs because the two neutral gray regions may have very different spectral properties as is illustrated in FIG. 3. Such pairs of colors that are different spectrally, but which appear to be the same visually are commonly called “metamaric colors.”

Using well-known color management techniques, it is possible to relate the scanner RGB code values to the corresponding color as perceived by the human vision system. The perceived colors are commonly represented in color spaces such as the well-known CIE XYZ and CIELAB color spaces. However, since the way the scanner “sees” color is dependent on the spectral characteristics of the imaging media, the relationship between scanner RGB code values and the perceived color will be different for different imaging media. Therefore if a color transform is created to map scanner RGB code values to corresponding CIELAB color values, or to some other color space such as a video RGB color space or a printer color space, this color transform will only be accurate for one particular imaging media. More specifically, different color transforms will generally be necessary to achieve accurate color reproduction for input images that are formed on different imaging media using different sets of colorants.

There are many applications where it is desirable to digitize images from a variety of different imaging media. For example, a user may have a shoebox full of family photographs and would like to make digital representations of those photographs for viewing and sharing with other family members. Therefore it is necessary to deal with any scanner metamerism errors that may be associated with a given scanner/imaging media combination. The simplest approach is to design the scanning system for a single reference input medium, and then to live with any errors that are introduced for other imaging media. However, in many cases the color reproduction errors can be very dramatic and quite objectionable. Therefore, this approach can be quite unsatisfying for cases where the scanner metamerism errors are substantial.

An alternative solution is to determine different color transforms for each different input medium. While this approach can provide very accurate color reproduction, it is necessary for the user to select the appropriate color transform for the input medium that is being scanned. This can result in a very confusing and cumbersome user interface. Therefore, there is a need for an automatic and user friendly method to correct for scanner metamerism errors in a digital imaging system.

Another problem that is often encountered when scanning collections of images is the problem of image organization. In U.S. Patent Application Publication No. 2006/0198559 entitled “Method for automatically organizing a digitized hardcopy media collection,” Manico et al. have disclosed a method for automatically organizing prints based on analysis of the photographic print watermark patterns, the disclosure of which is incorporated herein by reference. Manufacturers of photographic print materials often included watermark patterns on the back of photographic prints. The terminology watermark patterns as used in the present application refers to visible patterns that are placed on the back of photographic print materials during the manufacturing process. Such watermark patterns are typically printed on the photographic print materials using some form of printing process, such as offset or gravure printing. Often the watermark patterns contain manufacturer-specific content such as company names, logos or trademarks. Watermark patterns may also contain other types of content such as lines and various geometric patterns. Commonly the watermark patterns are printed in light-colored inks, such as light yellow, light blue or light gray inks, to minimize the likelihood that the watermark patterns will show through to be visible from the front side a photographic print. These watermark patterns were often modified with each succeeding generation of the photographic print materials, and therefore provide valuable information about the date of the photographic print.

U.S. Patent Application Publication No. 2007/0250532 to Beato, et al., entitled “Method for Automatically Generating a Dynamic Digital Metadata Record from Digitized Hardcopy Media,” discloses automatically generating a dynamic set of metadata from digitized hardcopy media. The method includes analyzing features of a hardcopy print including watermarks and physical print attributes to determine information about the print that can be used to aid in organization of image collections. U.S. Patent Application Publication No. 2007/0250529 to Beato, et al., entitled “Method for Automatically Generating a Dynamic Digital Metadata Record from Digitized Hardcopy Media,” extends this method to include information that can be gleaned from scanning a sequence of hardcopy prints corresponding to a customer's order.

U.S. Pat. No. 7,170,655 to Clifton, entitled “Automatic scan sensor image processing,” discloses a device that scans an image from source media and automatically detects the source media type being scanned. If an image type is detected that is associated with certain scan defects, automatic processing is applied to at least partially compensate for those scan defects. For example, scans of transparencies tend to be blurry, in which case a sharpening algorithm is applied to compensate for the blur.

U.S. Pat. No. 6,745,186 to Testa, et al., entitled “Product and method for organizing and searching digital images,” describes methods of organizing digital images by sorting or organizing scanned hardcopy images by physical characteristics including shape, size, cut, texture, border or finish.

U.S. Pat. No. 6,606,411 to Loui, et al., entitled “Method for automatically classifying images into events,” describes methods for separating a group of images into events on the basis of time or date. Long lapses of time are used as event boundaries. Thus, when grouping images for output products like albums or for organizing a database of images, the images are grouped by similar time stamps.

U.S. Pat. No. 6,636,648 to Loui, et al., entitled “Albuming method with automatic page layout,” describes methods for laying out album pages on the basis of time or date and content. What is meant by content in this patent is a basic image analysis that identifies similar colorations such as histograms.

U.S. Pat. No. 6,351,321 to McIntyre, et al., entitled “Data scanning and conversion system for photographic image reproduction,” describes methods for identifying camera exposed information such as date/time/exposure conditions on digitized print images and employing techniques to edit out, crop, enhance, and replace the camera exposed information.

### SUMMARY OF THE INVENTION

In accordance with the present invention there is provided a method for automatically applying color transforms to scanned input images from a digital color image scanner, wherein the input images maybe on a variety of different imaging media, comprising the steps of:

a) scanning a front side of an input image forming an image scan;

b) scanning a back side of the input image forming a back scan;

c) analyzing the image scan or the back scan to determine the imaging medium for the scanned input image;

d) selecting a color transform associated with the determined imaging medium; and

e) applying the color transform to the image scan to produce a corrected image scan.

The present invention provides the advantage that customized color transforms can be applied to scanned images according to the imaging medium. The customized color transforms can account for any interactions between the spectral characteristics of the imaging medium and the scanner spectral sensitivities.

It has the additional advantage that it can also apply appropriate color enhancements to correct for color fading characteristic of images printed on older imaging media.

It has the further advantage that separate color transforms can be applied to the back scan and the image scan in order to account for differences in the imaging media characteristics and image content.

These and other aspects, objects, features and advantages of the present invention will be more clearly understood and appreciated from a review of the following detailed description of the preferred embodiments and appended claims and by reference to the accompanying drawings.

### BRIEF DESCRIPTION OF THE DRAWINGS

In the detailed description of the preferred embodiments of the invention presented below, reference is made to the accompanying drawings in which:

FIG. 1 is graph showing human spectral sensitivity functions;

FIG. 2 is graph showing typical scanner spectral sensitivity functions;

FIG. 3 is a graph showing the spectral reflectances of two metamaric neutral patches;

FIG. 4 is a flowchart showing a method of selecting a color transform from a determined imaging media according to an embodiment of the present invention;

FIG. 5A is an illustration of the image (front) and non-image (back) surfaces of a photographic print input image including a manufacturer's watermark;

FIG. 5B is an illustration of the image (front) and non-image (back) surfaces of a photographic print input image including a manufacturer's watermark and an identified media shape characteristic;

FIG. 6A is an illustration of the non-image (back) surface of a photographic print input image including a first variation of a manufacturer's watermark pattern;

FIG. 6B is an illustration of the non-image (back) surface of a photographic print input image including a second variation of a manufacturer's watermark pattern;

FIG. 6C is an illustration of the non-image (back) surface of a photographic print input image including a third variation of a manufacturer's watermark pattern;

FIG. 7A is an illustration of the non-image (back) surface of a photographic print input image having an ink printed photofinishing process applied stamp including the date of print processing;

FIG. 7B is an illustration of the image (front) surface of a photographic print input image including an optically exposed photofinishing process applied date of print processing;

FIG. 7C is an illustration of the non-image (back) surface of a photographic print input image including a digitally printed photofinishing process applied indicia including a camera recorded time and date of image capture, film roll ID number, and film roll frame number; and

FIG. 8 is an illustration of an imaging medium LUT and a color transform selection LUT that can be used to determine color transforms based on information obtained a scanned image.

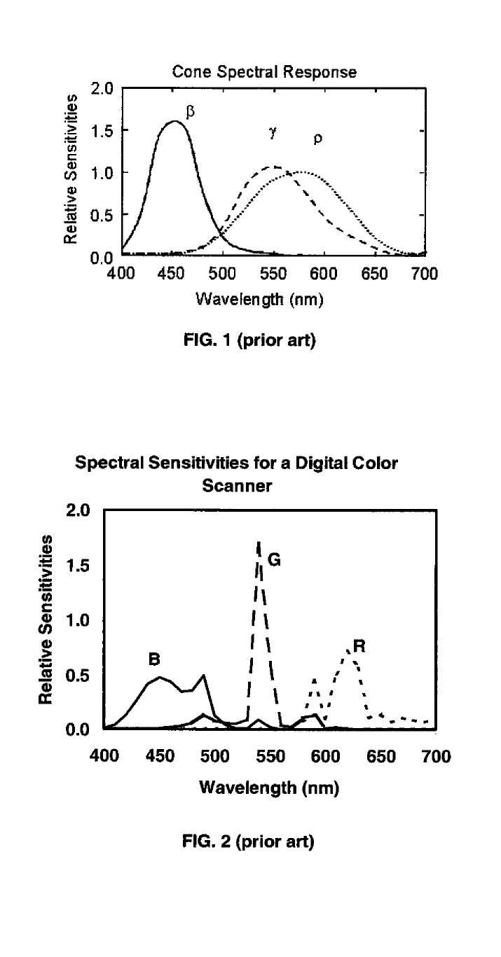

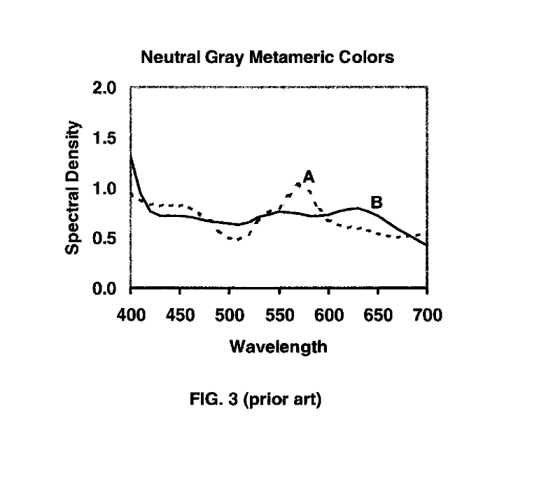

### DETAILED DESCRIPTION OF THE INVENTION

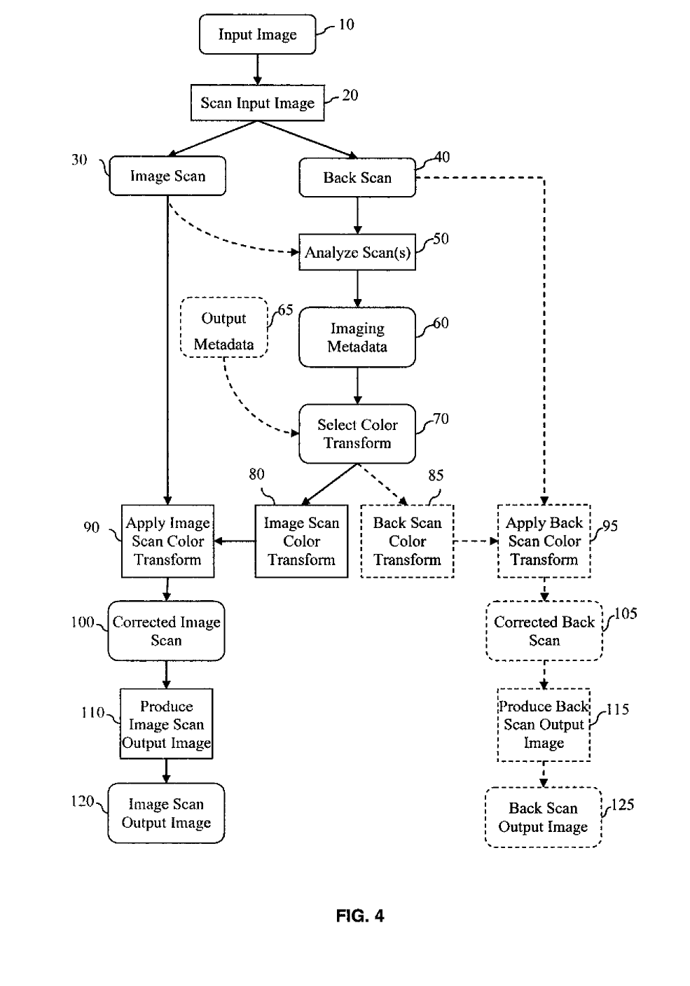

The present invention will now be described with reference to FIG. 4, which shows a flow diagram for a method of automatically applying a media-dependent color transform to scans obtained from an input image 10. First, a scan input image step 20 is used to scan the front and back sides of the input image 10 to produce an image scan 30 and a back scan 40, respectively. In one embodiment of the present invention, the input image 10 can be an optical photographic print produced by printing a photographic negative on conventional silver halide imaging medium. The input image 10 can also be a digital photographic print produced by printing a photographic image on conventional silver halide photographic print materials using a digital printer. Alternately, the input image 10 can he prints produced using other printing technologies such as thermal dye diffusion printers, ink jet printers, offset press printers, electro-photography, color laser printers, toner printers and other conventional and digital printing devices.

The method of the present invention is not limited to photographic prints but can be applied to other types of input images 10 besides photographic prints, such as documents, art work, magazines, books, newsprint, card stock and other image based media. Input image 10 can be produced on other such media which include: silver halide (AgX) photographic paper, Albumen paper, fiber based paper, bond paper, glossy paper, luster paper, high luster paper, semi-luster paper, matte paper, semi-matte paper, contrast paper, multigrade or variable-contrast paper, resin coated papers, offset print paper, transparencies, thermal imaging media, inkjet imaging media, canvas, artists drawing paper, linen, parchment, tapestry, dry-plate, tintype, daguerreotype and ambrotype media. Alternately, the input image 10 could have been produced on any media that a digital color image scanner is capable of scanning.

In a preferred embodiment of the present invention, the scan input image step 20 is performed using a high speed scanner, such as one of the Kodak i600 Series Scanners, that simultaneously scans both the front side and the back side of the input image 10. Such scanners are used in photographic kiosk systems for providing digitization services for collections of a user's photographic prints. Alternately, the scan input image step 20 can be performed using other types of scanners, such as flatbed scanners. In such cases, it would be necessary to scan the front of the input image 10 to produce the image scan 30 and then to physically turn the input image 10 over to scan the back of input image 10 to produce the back scan 40. In another embodiment of the present invention, a digital camera can be used with a copy stand to photograph the front and back side of the input image 10.

When a digital color scanner scans an input image 10, the sensor in the digital color image scanner will produce color values in a native scanner color space associated with the spectral sensitivities of the different sensor elements. Typically, the scanner color space will be an RGB color space corresponding to red, green and blue sensor spectral sensitivities. However, other types of encodings are also possible. For example, some scanners use a fourth color channel having a neutral spectral sensitivity. Depending on the scanner architecture, the scanner may leave the image in the native scanner color space, or it may convert the image to a standard color space such as sRGB. In such cases, the color transform used to convert the image will generally be optimized for one particular type of imaging media. The digital color image scanner may also include a number of other processing steps in its imaging chain. For example, it may apply dark current subtraction, gain correction, defect correction, sharpening, noise reduction, etc.

As discussed in the Background of the Invention section, digital color image scanners generally do not utilize sensors having color matching function sensitivities, and therefore scanned images from different input imaging media may not be directly compatible with one another. For example, if a scanner is optimized to scan a particular type of conventional silver halide imaging media, equal RGB values will be produced when a gray patch on that type of media is scanned. However, if the scanner is then used to scan an input image on another type of silver halide imaging media or an input image produced on a particular inkjet printer, a neutral gray patch may have RGB values that are significantly unbalanced. Furthermore, even if neutral gray patches have RGB values that are significantly balanced, the RGB values for color patches on two different imaging media that appear to match visually may be different in the scanned images. These artifacts are well-known in the art as scanner metamerism errors associated with scanning that particular imaging medium. Scanner metamerism errors arise from differences between the spectral sensitivities of the scanner and the spectral response of the human visual system.

U.S. Patent Application Publication No. 2008/0239334 to Jasinski, et al., entitled “Scanner Metamerism Correction,” which is incorporated herein by reference, describes a method for detecting scanner metamerism errors based on an analysis of the color balance of a scanned image based on the fact that certain imaging media appear to have a noticeable color cast when scanned on a particular scanner. This method is susceptible to errors due to misidentification of the imaging medium. In particular, it is difficult in many cases to distinguish between a color cast introduced by metamerism errors and a skewed color distribution associated with the scene content of a particular image. For example, a photograph of green forest may be difficult to distinguish from a scanned image having a green color cast. It is also not capable of distinguishing between imaging media that do not have large differences in their metamerism characteristics. The present invention solves these problems by determining the imaging medium using additional information about the imaging media that can be determined from the image scan 30 and the back scan 40.

In a preferred embodiment of the present invention, the analyze scan(s) step 50 is used to analyze the back scan 40 to identify the watermark pattern often found on the back of photographic prints. The identified watermark pattern is then associated with the input image as one piece of imaging metadata 60. The imaging metadata 60 is then used by a select color transform step 70 to determine the imaging medium for the input image 10 and to determine an image scan color transform 80 associated with the determined imaging medium.

Optional features of the present invention are illustrated in FIG. 4 using broken lines. A broken line is shown connecting the image scan 30 to the analyze scan(s) step 50, as an indication that the analyze scan(s) step 50 can be used to analyze either the image scan 30 or the back scan 40 or both scans in the process of determining the imaging metadata 60 that is used in the select color transform step 70.

The terminology “watermark patterns,” as used in the present application, refers to visible patterns that are placed on the back of photographic print materials during the manufacturing process. Such watermark patterns are typically printed on the photographic print materials using some form of printing process, such as offset or gravure printing. Often the watermark patterns contain manufacturer-specific content such as company names, logos or trademarks. Watermark patterns may also contain other types of content such as lines and various geometric patterns. Commonly the watermark patterns are printed in light-colored inks, such as light yellow, light blue or light gray inks, to minimize the likelihood that the watermark patterns will show through, making them visible from the front side a photographic print. Manufacturers often modified the watermark patterns with each succeeding generation of the photographic print materials, and therefore they provide valuable information about the imaging medium of an input image 10. The characteristics of watermark patterns are described in more detail in U.S. Patent Application Publication No. 2006/0198559 to Manico et al., entitled “Method for automatically organizing a digitized hardcopy media collection,” which is incorporated herein by reference.

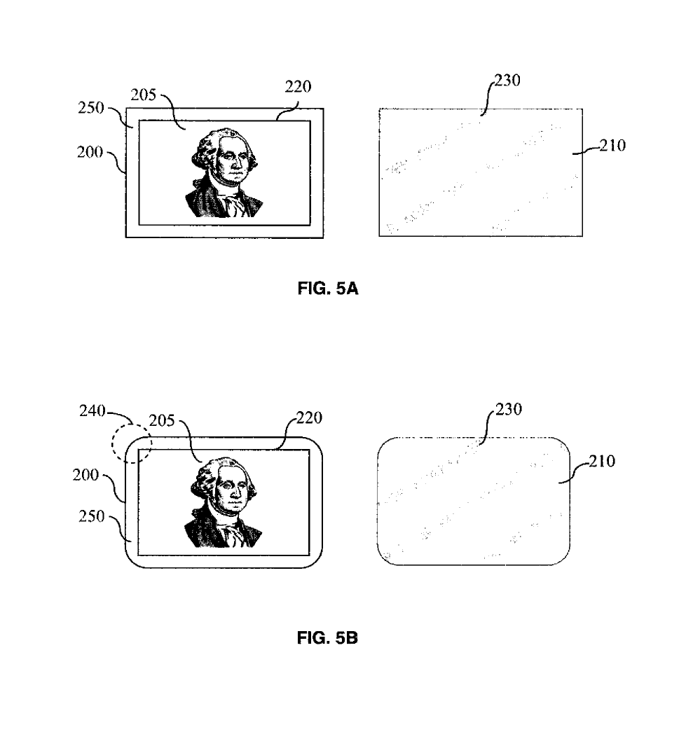

FIGS. 5A and 5B illustrate additional characteristics of a photographic print input image 200 that can be used to provide imaging metadata 60 pertaining to the input image 10. FIG. 5A is an illustration of an image (front) surface 220 and a non-image (back) surface 210. Watermark pattern 230, which is applied by the photographic manufacturer, is recorded on the non-image (back) surface 210 and is correlated to manufacturer media specifications which could include but is not limited to: manufacturing date, colorant sets used, surface texture, spectral reflectivity, brightness, colorant fade factors, surface sheen, base tone, image tone, contrast and other manufacturer specified characteristics. The image (front) surface 220 includes image border 250 that defines an image area 205.

FIG. 5B is an illustration of photographic print input image 200 having a unique media shape characteristic 240, in this case ½ (1.27 cm) radius rounded corners. Non-image (back) surface 210 includes a watermark pattern 230 which matches the watermark depicted in FIG. 5A. The shape characteristic 240 can be noted by the analyze scan(s) step 50 and can be stored as an attribute of the imaging metadata 60, together with other attributes such as the image size and the image border width.

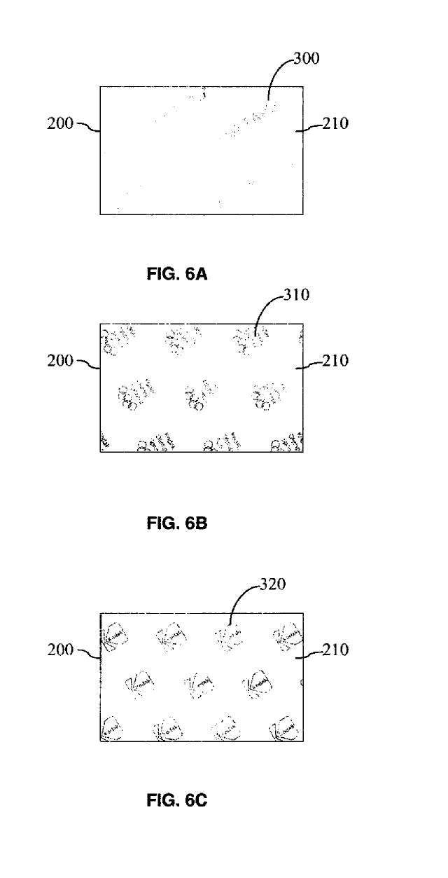

FIGS. 6A, 6B, and 6C illustrate different types of watermark styles used by imaging media manufacturers over time. Manufacturers include slight variations to the master roll watermarks such as adding a line above or below a designated character in the case of an alphanumeric watermark. This coding technique is not obvious or even apparent to the user, but is used by the manufacturer in order to monitor manufacturing process control or to identify the location of a manufacturing process problem if a defect is detected. Different variations are printed at set locations across the master media roll. When finished rolls are cut from the master roll they retain the specific coded watermark variant applied at that relative position along the master roll. In addition, manufacturers maintain records of the various watermark styles, coding methodologies, media characteristics and when specific watermark styles were introduced into the market. More detail of this can be found in U.S. Patent Application Publication No. 2007/0250532 to Beato et al., entitled “Method for automatically generating a dynamic digital metadata record from digitized hardcopy media,” which is incorporated herein by reference. FIG. 6A is an illustration of the non-image (back) surface 210 of a photographic print input image 200 including a first watermark pattern 300 which identifies a particular imaging medium. FIG. 6B is an illustration of the non-image (back) surface 210 of a photographic print input image 200 including a second watermark pattern 310, in this case a sponsorship type watermark pattern that includes text and graphic and was designed to commemorate a manufacturer's sponsorship of a particular event such as the Olympics. FIG. 6C is an illustration of the non-image (back) surface 210 of a photographic print input image 200 including a third watermark pattern 320. Each sample depicted in FIGS. 6A, 6B, and 6C, has a different watermark pattern that can be used to provide imaging metadata 60 about the corresponding input image 10, and can be useful for determining the corresponding imaging medium.

Since the manufacturing date histories and media specifications of the various watermark patterns are known to the manufacturer, images having these watermarks can be identified with this imaging metadata 60 even if no other information is available. The various recognized watermark styles with known manufacturing dates provides a method for determining the imaging medium, as well as providing a date of image origination when no other date information is available and providing another criterion for matching, grouping, sorting, and sequencing the corresponding input image 10.

There are various ways to identify the watermark pattern 230 in the analyze scan(s) step 50. In a preferred embodiment of the present invention the watermark pattern is identified using a cross-correlation process, as is described in more detail in co-pending U.S. patent application Ser. No. 12/491,268 to A. Scalise, et al., entitled: “Dating Images from Scanned Watermarks”, which is incorporated herein by reference. In this cross-correlation process, a watermark reference image is translated horizontally and vertically across the back scan 40. When the two images are similar and are properly aligned, a higher correlation signal is obtained; when the two images are dissimilar or are not aligned a lower correlation signal is obtained. Mathematically, the cross-correlation operation is given by the following equation:

$$C ( x , y ) = B ( x , y ) * W ( x , y ) = {\sum }_{{x}_{0} = 1}^{{N}_{x}} {\sum }_{{y}_{0} = 1}^{{N}_{y}} B ( x + {x}_{0} , y + {y}_{0} ) W ( {x}_{0} , {y}_{0} ) \qquad ( 1 )$$

where C(x, y) is a cross correlation image, B(x, y) is a back scan 10, W(x, y) is a watermark reference image, Nₓ and N_{y} are the horizontal and vertical sizes of the watermark reference image, respectively, x and y are the row and column indices, and x₀ and y₀ are loop indices. This calculation is repeated for each x and y position to determine a full cross-correlation image. A threshold can be applied to the cross correlation image. If any peaks in the cross-correlation image exceed the threshold, then the back scan 40 is identified as containing the particular watermark pattern. The identified watermark pattern would be imaging metadata 60 that can be used in the process of determining the imaging medium in the select color transform step 70.

There may be cases where two watermark patterns differ only in the color and not the geometric shape. In such cases, the color of the watermark pattern in the back scan 40 is determined in the analyze scan(s) step 50 by examining the color values of the non-white regions. The resulting color value would be an attribute of the imaging metadata 60 that can be compared to the reference color(s) for the watermark pattern which would aid in the identification of the watermark pattern.

If an input image 10 has an unrecognized watermark style, that watermark pattern is recorded and stored as imaging metadata 60 and can still be useful for purposes such as image organization. If a photofinisher or user applied date or other information indicative of an event, time frame, location, subject identification, or the like is detected, that information would be stored as imaging metadata 60 and can be used to establish a chronology or other organizational structure for subsequent images including the previously unidentified watermark. The detected date can also be useful for determining the imaging medium by narrowing the possible imaging media down to those available on the detected date.

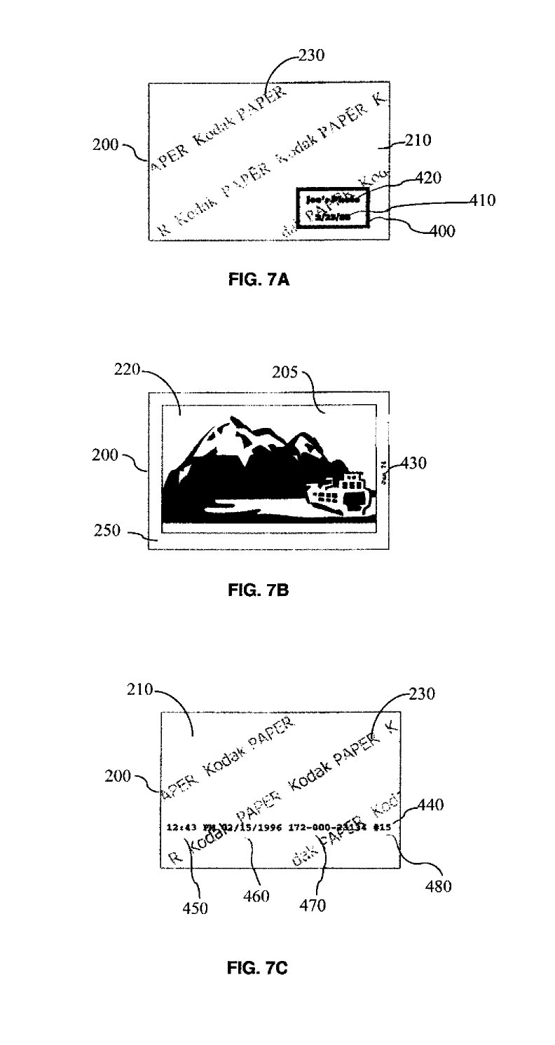

In another embodiment of the present invention, the back of the input image 10 contains back printing. As shown in FIG. 7A, such back printing can include a photofinisher applied ink stamp 400 printed on the non-image (back) surface 210 of a photographic print input image 200. The photofinisher applied ink stamp 400 often includes a date stamp 410 indicating the date of processing. Frequently, photofinishing providers, photography studios or professional photographers will also include a custom graphic 420 to identify themselves. If the presence of back printing in the back scan 40 is detected in the analyze scan(s) step 50, then an optical character recognition (OCR) algorithm or a pattern matching technique can be used to identify the alphanumeric characters or graphic in the back printing, as is well-known in the art. The alphanumeric characters can then be analyzed to extract a date string or other information pertaining to the photofinishing lab, photofinishing process or other photofinishing related imaging metadata 60. Identified custom graphics or insignias can be correlated to other information pertaining to the photofinishing lab, photofinishing process or other photofinishing related imaging metadata 60 and can be used in the process of determining the imaging medium.

If the back scan 40 is determined to include labels added by a user (e.g., handwritten notations), the labels can be analyzed to determine whether they contain any information including dates. Algorithms for extracting alphanumeric characters from handwritten text are also well-known in the art, and are commonly used for applications such as mail sorting. Such algorithms can be applied to search for any strings of numbers and characters that may provide clues as to the date of the print or other information that can be useful in the process of determining the imaging medium.

In FIG. 7B, the image (front) surface 220 of a photographic print input image 200 includes a photofinisher applied, optically exposed processing date 430 in the image border 250. In some cases, there may be an image capture date printed in the image area 205 that can be detected. For example, some cameras had optional features which allowed a date to be automatically added to the image at the time of image capture. If the presence of a processing date 430 or an image capture date is detected in the image scan 30 using the analyze scan(s) step 50, then an optical character recognition (OCR) algorithm can be applied to identify the alphanumeric characters. The alphanumeric characters can then be analyzed to extract a date which can then be used as imaging metadata 60. This analysis is not limited to optical character recognition but could be performed by any alphanumeric character recognition methods well-known in the art. Additional items of imaging metadata 60, such as color saturation of the image, size and aspect ratio of the image and the presence and characteristics of any borders present on the image can also be obtained by analyzing the image scan 30.

In FIG. 7C, the non-image (back) surface 210 of a photographic print input image 200 includes photofinisher applied metadata 440. The photofinisher applied metadata 440 can include a time stamp 450 and a date stamp 460 typically representing the capture time and date of the image, respectively. The photofinisher applied metadata 440 can also include a film ID number 470 and a film frame number 480. All the related information of the types presented would be detected and translated in the analyze scan(s) step 50 for creating imaging metadata 60 to be used in the process of determining the imaging medium in the select color transform step 70. The imaging metadata 60 is also useful operations such as identifying images and matching, grouping, sorting or sequencing groups of images.

Returning now to a discussion of FIG. 4, a number of characteristics of the imaging media can be extracted or derived from the back scan 40 or image scan 30 and used by the analyze scan(s) step 50 to produce imaging metadata 60 as has been discussed above. Imaging metadata 60 that can be useful for determining the imaging medium and for other purposes would include, but is not limited to: the detected watermark pattern, image height, image width, image aspect ratio, image orientation (portrait/landscape), border size, border style, border density, machine text, text font type, photofinisher logo/graphic, photofinishing date/time, image capture/and time, handwritten annotations, color cast, color saturation, film roll identification, print number (of recorded sequence) and media group.

Additional data that can be saved as imaging metadata 60 would include information about the scanner or the digital camera used in the scan input image step 20. For example, characteristics such as make, model, time and date of digitization, manufacturer maker notes, and spectral sensitivities can all be useful in the process of selecting an appropriate image scan color transform 80. Often this information can be extracted from metadata in the image files produced by the scanner or digital camera. Such metadata is commonly stored according to the Exchangeable Image File Format (EXIF). In other cases, it may be necessary to obtain this information by performing tests on the scanner or the digital camera (e.g., to determine the spectral sensitivities).

The image select color transform step 70 selects an image scan color transform 80 responsive to the imaging metadata 60. In a preferred embodiment of the present invention, the imaging metadata 60 is used to identify the imaging medium for the input image 10, and an image scan color transform 80 is selected that has been optimized for the identified imaging medium. An example of how the imaging metadata 60 can be used to identify the imaging medium would be when the imaging metadata 60 contains information about a watermark pattern that was detected on the back scan 40 by the analyze scan(s) step 50. In this case, the imaging metadata 60 would include an identification of the particular watermark pattern. The watermark pattern can then be used to determine the imaging medium for the input image 10.

If the imaging metadata 60 does not include information about an identified watermark pattern, other pieces of metadata can be analyzed to aid in making an identification of the imaging medium. For example, if an image capture date were detected from the image scan as described earlier, then it would be reasonable to assume that the imaging medium would be the predominant imaging medium that was used by photofinishers during that time period. Similarly, the image size and border style can provide valuable clues about the date when a particular input image was originally printed, and in turn what imaging medium was probably used to print the image. Even if the identification of the imaging medium is not certain, the select color transform step 70 can make an assessment of the most probable imaging medium and use this information to select an appropriate color transform.

It should be noted that there is a wide range of different imaging media that can be scanned on the digital color image scanner. The metamerism characteristics of many different types of imaging media may be quite similar, and therefore accurately distinguishing the exact imaging media may not be needed if like media can be grouped together based on other imaging metadata 60 criteria allowing a common color transform to be used. Precise identification of the exact imaging media is not a limitation of the present invention.

In the preferred embodiment of the present invention, the select color transform step 70 selects an image scan color transform 80, and optionally a back scan color transform 85, that is designed to correct for scanner metamerism errors associated with scanning an input image 10 having the identified imaging medium on the particular digital color image scanner. The image scan color transform 80 and the back scan color transform 85 for a particular imaging medium/scanner combination is preferably determined by scanning a test target printed on the actual imaging medium having patches of known color. Well-known methods for building color transforms can then be used to build a color transform that will map the scanner RGB values to the corrected color values. Alternatively, a color transform can also be determined from information including the scanner spectral sensitivities and the spectral characteristics of the imaging medium using methods well-known in the art. The color transforms will commonly he in the form of a three-dimensional look-up table. Optionally, they can be in other forms including various combinations of look-up tables, matrices, decision trees, databases and mathematical functions.

In the preferred embodiment of the present invention, image scan color transforms 80 and optionally back scan color transforms 85 are determined ahead of time for the most common types of imaging media that are likely to be encountered by the imaging system. The select color transform step 70 then simply selects a color transform appropriate for the identified imaging medium.

In many cases, a given image scan color transform 80 or back scan color transform 85 will be appropriate for a family of imaging media types that share similar imaging media characteristics, the most important imaging media characteristic being the colorant spectra. Another important imaging media characteristic would be the image fade characteristics. In these cases, the select color transform step 70 can select the same image scan color transform 80 or back scan color transform 85 for a grouping of different imaging media types.

The determination of optimized color transforms that exactly corrects for the scanner metamerism errors can be a time consuming process. In some cases, it may not be worthwhile to spend a lot of effort building color transforms for media that will be rarely encountered. In such cases, it may be possible to build simplified color transforms that substantially improve the image quality even though they do not exactly correct for the scanner metamerism errors. For example, the most objectionable characteristic of scanner metamerism errors is typically an overall color cast that is present on the scanned image. For example, the images may appear to have a greenish tint. A substantial improvement in the image quality can be realized by performing a simple color balance adjustment to remove the color cast. Such color balance adjustments can be implemented using simple color transforms that apply one-dimensional color balance look-up tables to each of the color channels of the scanned image. In one embodiment of the present invention, the amount of color balance shift appropriate for a particular imaging medium is determined by scanning a small number of images on the imaging medium and having an observer perform a manual color balance adjustment using tools that are well-known in the image processing art. A color transform in the form of set of one-dimensional color balance look-up tables can then be stored for use as the image scan color transform 80 or the back scan color transform 85 when the particular imaging medium is detected.

In some cases, it may be desirable for the color transform to modify the colors in the input image rather than faithfully reproducing them. For example, if the input image is determined to be on an older color imaging media, it is likely that the input image has a substantial degree of image fade. In this case, it may be desirable to use a color transform that is designed to correct for the image fade in order to produce an enhanced image. The color transform can be designed based on the known dye fade characteristics of the determined imaging medium, together with the determined age of the imaging medium. It may also be desirable to incorporate color enhancements into back scan color transforms 85 in order to increase the contrast of handwritten notations that may be contained in the back scan 40.

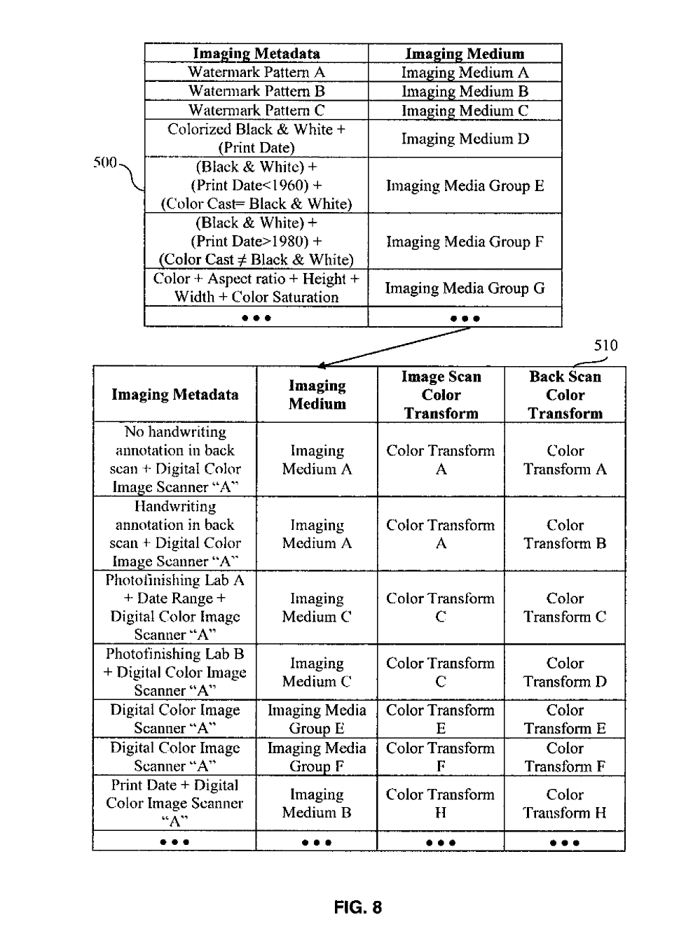

FIG. 8 shows an example of an imaging medium look up table (LUT) 500 that can be used in the select color transform step 70 to determine the imaging medium based on the imaging metadata 60 in one embodiment of the present invention. The imaging medium look-up table (LUT) 500 presented in FIG. 8 is not intended to be exhaustive, but is shown only as an example. In the case where the imaging metadata indicates that Watermark Pattern “A” was detected in the analyze scan(s) step 50, the imaging medium LUT 500 identifies the imaging medium as Imaging Medium “A.” The identified input medium is then passed to a color transform selection look up table (LUT) 510 to determine the image scan color transform 80 and the back scan color transform 85. If, for example, the imaging metadata 60 indicates that no handwritten annotation was detected in the back scan 40 during the analyze scan(s) step 50, the color transform selection LUT 510 identifies both the image scan color transform 80 and the back scan color transform 85 as Color Transform “A,” which is a color transform that corrects for scanner metamerism errors associated with scanning input images 10 on Imaging Medium “A” using Digital Color Image Scanner “A”.

If the imaging metadata 60 indicates that a handwritten annotation was detected in the analyze scan(s) step 50, the color transform selection LUT 510 identifies the image scan color transform 80 as Color Transform “A” as mentioned before, but the back scan color transform 85 is identified as Color Transform “B”. Color Transform “B” can include enhancements that increase contrast and color saturation of the back scan 40 to make the handwritten annotation more legible or improve automated recognition.

In another example, if the imaging metadata 60 indicates that Watermark Pattern “C” was detected in the analyze scan(s) step 50, the imaging medium LUT 500 identifies the imaging medium as Imaging Medium “C.” If the imaging metadata 60 also indicates that the input image 10 was scanned using Digital Color Image Scanner “A” and that a Photofinisher Lab B logo was detected, then the color transform selection LUT 510 would identify the image scan color transform 80 as Color Transform “C” to correct for scanner metamerism errors but the back scan color transform 85 would be identified as Color Transform “D”. Color Transform “D” can include enhancements to make the logo or photofinishing related text more legible or to improve automated recognition.

In the case where the imaging medium cannot be determined exactly from the imaging metadata 60 for a given input image 10, other items of imaging metadata 60 can be used to identify an appropriate imaging media group, wherein the imaging media in the group arc known to have similar characteristics.

For example, consider the case where the imaging metadata 60 indicates that an input image 10 was a black & white image. The imaging medium may be a silver halide black & white photographic paper. However, it could also be a black-and-white chromogenic film designed for processing in color negative chemistry and printing on color negative paper to produce black & white prints. If the imaging metadata 60 indicates that the print date was earlier than 1960, and the color cast is equal to a typical black & white photographic paper base or image tone, there will be a high probability that the imaging medium is silver halide black & white photographic paper. In this case, the imaging medium LUT 500 identifies the imaging medium as Input Media Group “E” and appropriate color transforms can be selected using the color transform selection LUT 510.

If, on the other hand, the imaging medium was color photographic paper such that the ‘Black’ was produced from a mixture of dyes that can produce scanner metamerism errors, there is often a shift in image tone or a color cast when the print is scanned. Dye fade with age will also produce a color cast. If the print date is determined to be later than 1980 and color cast of the image is not equal to a typical black & white photographic paper, there is a high probability that the imaging medium is color photographic paper. In this case, the imaging medium LUT 500 identifies the imaging medium as Input Media Group “F” and appropriate color transforms can be selected using the color transform selection LUT 510.

In some applications, a collection of images may be scanned that are known to be on the same imaging medium. In this case, it is not necessary to analyze every scanned image to determine the imaging medium. Once the imaging medium has been determined for one of the input images, the selected color transforms determined for that input image can be used to transform other scanned input images as well.

Referring again to FIG. 4, the apply image scan color transform step 90 applies the image scan color transform 80 to the image scan 30 to produce a corrected image scan 100. The corrected image scan 100 is then used by the produce image scan output image step 110 to form an image scan output image 120. Similarly, an apply back scan color transform step 95 can optionally be used to apply the back scan color transform 85 to the back scan 40 to produce a corrected back scan 105. The corrected back scan 105 can then be used by the produce back scan output image step 115 to create a back scan output image 125.

In some applications, the image scan output image 120 and the back scan output image 125 will be printed images produced on a hardcopy printing device. In this case it will generally be desirable that the corrected image scan 100 and the corrected back scan 105 be in a color space appropriate for printing on the intended hardcopy printing device. In other applications, the image scan output image 120 and the back scan output image 125 will be softcopy images intended for devices such as televisions, computer monitors, PDA's or cell phones. In this case, it will generally be desirable that the corrected image scan 100 and the corrected back scan 105 be in a color space appropriate for printing on the intended softcopy device. For many applications using softcopy displays, it will be appropriate for the output color space to be a color space associated with a standard softcopy display, such as the well-known sRGB color space.

In a preferred embodiment of the present invention, the selected color transforms will be designed such that the color of the output image matches the color of the input image when the two images are viewed under defined viewing conditions. It may therefore be necessary for the select color transform step 70 to select different color transforms depending on the intended output media and viewing conditions. Output metadata 65 can be used to supply information pertaining to the desired output conditions such as intended output device, output media and viewing conditions. The output metadata can be generated by the system or user input. The method of the present invention is not limited by the presence or use of output metadata 65. In some applications, the output conditions can be fixed. In this case, it may not be necessary for the select color transform step 70 to make use of any output metadata 65.

In some applications it may be desirable for the corrected image scan 100 and the corrected back scan 105 to be in a standard color space, such as sRGB, independent of the intended output device. In this case, it is not necessary for the selected color transforms to account for the intended output device and viewing conditions. Rather, any color transforms that are necessary to account for differences between the standard color space and the final output space would be applied as part of the produce image scan output image step 110 and the produce back scan output image step 115.

In a baseline configuration, the image scan color transform 80 and the back san color transform 85 are applied directly to the image scan 30 and the back scan 40. In alternate configurations, the image scan 30 and the back scan 40 are first transformed to an intermediate color space (e.g., sRGB) before the color transforms are applied.

Often, the conversion to an intermediate color space can introduce undesirable artifacts such as quantization or contouring. An alternate configuration uses the information from an initial low resolution pre-scan of the input image for the analyze scanned image step in order to determine the scanner metamerism correction color transform required which is then applied to a second full resolution scan, using the apply color transform step. Alternately, the initial scan may be a full resolution scan of the input image and a second scan performed only if the analyze scanned image step determines that correction is required. Otherwise, the initial scan image can be used without application of the apply color transform step.

One embodiment of the present invention is a system including a scanner for scanning a front side and a back side of input images, where the input images may be on a variety of different imaging media. The system operates by automatically determining the imaging medium for an input image and applying color transforms to scanned input images in order to correct for interactions between the scanner and the imaging medium. The system includes one or more processors for analyzing the image scan and the back scan to determine the imaging medium for the scanned input image; selecting a color transform associated with the determined imaging medium; and applying the color transform to the image scan to produce a corrected image scan. The system can also include one or more output devices for producing output images intended for viewing by a human observer.

A computer program product can include one or more storage medium, for example; magnetic storage media such as magnetic disk (such as a floppy disk) or magnetic tape; optical storage media such as optical disk, optical tape, or machine readable bar code; solid-state electronic storage devices such as random access memory (RAM), or read-only memory (ROM); or any other physical device or media employed to store a computer program having instructions for controlling one or more computers to practice the method according to the present invention.

The invention has been described in detail with particular reference to certain preferred embodiments thereof, but it will be understood that variations and modifications can be effected within the spirit and scope of the invention.

### PARTS LIST

10 Input Image(s)
20 Scan Input Image Step
30 Image Scan
40 Back Scan
50 Analyze Scan(s) Step
60 Imaging Metadata
65 Output Metadata
70 Select Color Transform Step
80 Image Scan Color Transform
85 Back Scan Color Transform
90 Apply Image Scan Color Transform Step
95 Apply Back Scan Color Transform Step
100 Corrected Image Scan
105 Corrected Back Scan
110 Produce image scan output image step
115 Produce back scan output image step
120 Image scan output image
125 Back scan output image
200 Photographic print input image
205 Image Area
210 Non-image (back) surface
220 Image (Front) surface
230 Watermark pattern
240 Shape characteristic
250 Image border
300 First watermark pattern
310 Second watermark pattern
320 Third watermark pattern
400 Photofinisher applied ink stamp
410 Date stamp
420 Custom graphic
430 Processing date
440 Photofinisher applied metadata
450 Time stamp
460 Date stamp
470 Film ID number
480 Film frame number
500 Imaging medium look-up table (LUT)
510 Color Transform Selection look-up table (LUT)

1. A method for automatically applying color transforms to scanned input images obtained using a digital color image scanner, wherein the input images are on a variety of different imaging media, comprising:
a) scanning a front side of an input image forming an image scan;
b) scanning a back side of the input image forming a back scan;
c) analyzing the image scan or the back scan to determine the imaging medium for the scanned input image;
d) selecting a color transform associated with the determined imaging medium; and
e) applying the color transform to the image scan to produce a corrected image scan.

2. The method of claim 1 wherein the input image is a photographic print on a silver halide imaging medium.

3. The method of claim 1 wherein the input image is a print from an inkjet printer or a thermal printer.

4. The method of claim 1 wherein the scanning steps are performed using a high speed scanner that simultaneously scans both the front side and the back side of the input image.

5. The method of claim 1 wherein the scanning steps are performed using a flatbed scanner.

6. The method of claim 1 wherein the scanning steps are performed using a digital camera.

7. The method of claim 1 wherein both the image scan and the back scan are analyzed in step c).

8. The method of claim 1 wherein the back of the input image contains a watermark pattern, and step c) includes analyzing the back scan to identify the watermark pattern and using the identified watermark pattern in the process of determining the imaging medium.

9. The method of claim 8 wherein the watermark pattern is identified using a cross-correlation process.

10. The method of claim 8 wherein the color of the watermark pattern is analyzed in the process of identifying the watermark pattern.

11. The method of claim 1 wherein the back of the input image contains back printing, and step c) includes analyzing the back printing in the process of determining the imaging medium.

12. The method of claim 11 wherein the back printing includes information printed during a photofinishing process.

13. The method of claim 1 wherein the selected color transform corrects for scanner metamerism errors associated with scanning input images on the determined imaging medium using the digital color image scanner.

14. The method of claim 1 further including the step of producing an output image.

15. The method of claim 14 wherein the output image is a digital image appropriate for display on a standard softcopy device, and wherein the corrected image scan is in a color space associated with the standard softcopy device.

16. The method of claim 14 wherein the output image is a hardcopy print produced using a particular hardcopy printing device, and wherein the corrected image scan is in a color space appropriate for printing on the particular hardcopy printing device.

17. The method of claim 14 wherein the color of the output image matches the color of the input image under defined viewing conditions.

18. The method of claim 14 wherein the color of the output image is enhanced relative to the color of the input image.

19. The method of claim 18 wherein the color of the output image is enhanced to correct for the image fade.

20. The method of claim 1 further including applying a back scan color transform to the back scan to produce a corrected back scan, wherein the back scan color transform is selected responsive to the determined imaging medium.

21. The method of claim 1 wherein the selected color transform for the determined imaging medium is applied to other scanned input images that are known to be on the same imaging medium.

22. A system for automatically applying color transforms to scanned input images, wherein the input images are on a variety of different imaging median comprising:
a) a scanner for scanning a front side of an input image forming an image scan;
b) a scanner for scanning a back side of the input image forming a back scan; and
c) one or more processors for:
i) analyzing the image scan or the back scan to determine the imaging medium for the scanned input image;
ii) selecting a color transform associated with the determined imaging medium; and
iii) applying the color transform to the image scan to produce a corrected image scan.
